(19) United States
(12) Patent Application Publication
(10) Pub. No.: US 2025/0392020 A1
(43) Pub. Date: Dec. 25, 2025

(54) Battery Sampling Assembly and Battery Pack

(71) Applicant: BATTERO TECH CORPORATION LIMITED, Shanghai (CN)

(72) Inventors: Lin ZHENG, Shanghai (CN); Han BAO, Shanghai (CN)

(73) Assignee: BATTERO TECH CORPORATION LIMITED, Shanghai (CN)

(21) Appl. No.: 18/880,359

(22) PCT Filed: Dec. 8, 2022
(86) PCT No.: PCT/CN2022/137503

§ 371 Date: Dec. 31, 2024

(30) Foreign Application Priority Data
Jul. 18, 2022 (CN) 202210840740.0

(51) Int. Cl. H01M 50/569; G01R 31/36; H01M 50/204; H01M 50/507; H01M 50/516; H01M 50/519

(52) U.S. Cl. CPC H01M 50/569; G01R 31/3644; H01M 50/204; H01M 50/507; H01M 50/516; H01M 50/519

(57) ABSTRACT

A battery sampling assembly and a battery pack are provided. The battery sampling assembly includes at least one metal sampling sheet and at least one insulating film. Each of the metal sampling sheet includes a body. A first end portion and a second end portion are arranged at two ends of the body. The first end portion is configured to be electrically connected with a busbar. The second end portion is configured to be electrically connected with a circuit board. The insulating film covers the body of the metal sampling sheet.

### CROSS-REFERENCE TO RELATED APPLICATION

The present application claims priority to Chinese Patent Application No. 2022108407400, entitled “BATTERY SAMPLING ASSEMBLY AND BATTERY PACK” filed with the State Intellectual Property Office of P. R. China on Jul. 18, 2022, which is incorporated by reference in its entirety.

### TECHNICAL FIELD

The present disclosure relates to the technical field of batteries, specifically to a battery sampling assembly and a battery pack.

### BACKGROUND

The existing battery cells are all provided with pole columns on different sides of each of the battery cells, and the pole columns on two sides need to be transferred to a same side to facilitate a collection of information of battery packs. In the existing transfer modes, a wire harness transfer mode and a flexible circuit board transfer mode are mostly used. If the wire harness transfer mode is used, the structure is complex, the wire harnesses are numerous, the connection efficiency is low, and the phenomena of short circuits, missed connection and the like easily occur in wire harnesses. If the flexible circuit board transfer mode is used, two transfer processes are required, the structure is complex, the connection efficiency is low, and the cost is high. That is, the existing transfer mode is complex in structure, low in connection efficiency and high in cost.

### SUMMARY

The objective of the present disclosure is, for example, to provide a battery sampling assembly and a battery pack, which is able to simplify a sampling structure and reduce the cost.

The embodiments of the present disclosure is able to be implemented as follows:

According to a first aspect, the present disclosure provides a battery sampling assembly, including:
at least one metal sampling sheet, each of the at least one metal sampling sheet including a body, and a first end portion and a second end portion which are arranged at two ends of the body, the first end portion being configured to be electrically connected with a busbar, and the second end portion being configured to be electrically connected with a circuit board; and
at least one insulating film, the at least one insulating film covering the body of the at least one metal sampling sheet.

In an optional implementation, a ratio of a width to a thickness of the each of the at least one metal sampling sheet is 10-100.

In an optional implementation, a thickness of the each of the at least one metal sampling sheet is greater than or equal to 0.05 mm.

In an optional implementation, the body of the each of the at least one metal sampling sheet includes a first surface and a second surface which are arranged oppositely, and the at least one insulating film covers the first surface and the second surface respectively.

In an optional implementation, a thickness of each of the at least one insulating film is 0.03 mm-0.5 mm.

In an optional implementation, the body of the each of the at least one metal sampling sheet further includes a side surface, the side surface is connected with the first surface and the second surface respectively, and the side surface is provided with the at least one insulating film.

In an optional implementation, two insulating films are provided, the first surface is provided with one insulating film in the two insulating films, the second surface is provided with one insulating film in the two insulating films, and the two insulating films on two sides of the first surface and the second surface are in compression joint on the side surface.

In an optional implementation, the at least one insulating film is provided with through holes.

In an optional implementation, a plurality of metal sampling sheets are provided, each of the through holes is located between two adjacent metal sampling sheets in the plurality of metal sampling sheets.

In an optional implementation, an insulating film of the at least one insulating film located on a side of the first surface is provided with through holes, an insulating film of the at least one insulating film located on a side of the second surface is provided with through holes, and the through holes on two sides are arranged correspondingly or arranged in a staggered mode.

In an optional implementation, a length of the first end portion and a length of the second end portion are greater than or equal to 5 mm respectively.

In an optional implementation, the each of the at least one metal sampling sheet is provided with a buffer section, and a length of the each of the at least one metal sampling sheet is configured to be adjusted by the buffer section.

In an optional implementation, the first end portion and the second end portion are respectively provided with straight sections, and a length of each of the straight sections is greater than or equal to 3 mm.

In an optional implementation, the buffer section is arranged on at least one of the first end portion, the second end portion and the body.

In an optional implementation, the buffer section is arranged on the first end portion and the second end portion, the buffer section includes a first subsection and a second subsection which are connected with each other, and the first end portion and the second end portion are respectively provided with straight sections; and the first subsection is connected with the body, and the second subsection is connected with a corresponding straight section of the straight sections.

In an optional implementation, the buffer section is arranged on the body, the buffer section includes a first arc portion and a second arc portion which are connected with each other, and a concave direction of the first arc portion is opposite to a concave direction of the second arc portion.

In an optional implementation, the at least one metal sampling sheet and the at least one insulating film are fixed by colloid bonding.

In an optional implementation, a plurality of metal sampling sheets are provided, and a distance between two adjacent metal sampling sheets in the plurality of metal sampling sheets is greater than or equal to 2 mm.

According to a second aspect, the present disclosure provides a battery pack, including:
a plurality of cells;
busbars which are separately arranged on two sides of the cells and are electrically connected with the plurality of cells respectively;
a circuit board which is arranged on a side of the cells, at least one busbar of the busbars located on a same side of the cells as the circuit board being electrically connected with the circuit board; and
at least one battery sampling assembly as claimed in any one of claims 1 to 18, wherein the first end portion is electrically connected with a busbar on a side away from the circuit board, and the second end portion is electrically connected with the circuit board.

In an optional implementation, the first end portion of the each of the at least one metal sampling sheet is welded to the busbar on the side away from the circuit board.

The embodiments of the present disclosure have beneficial effects, for example:

The battery sampling assembly provided in the embodiments of the present disclosure includes the metal sampling sheets and the insulating films arranged on the metal sampling sheets, and two ends of each of the metal sampling sheets are electrically connected with the busbar and the circuit board respectively, so that a sampling of the battery cells is able to be achieved, the structure is simple, each of the metal sampling sheets is easy to install and locate, the connection is convenient, and the cost is low.

The battery pack provided in the embodiments of the present disclosure includes the above battery sampling assembly, the sampling structure is simple, the battery pack is convenient to assemble, and the increase in sampling efficiency and stability is facilitated.

### BRIEF DESCRIPTION OF THE DRAWINGS

To illustrate the technical solutions in the embodiments of the present disclosure more clearly, the following briefly introduces the accompanying drawings required in the embodiments. It should be understood that the following accompanying drawings only show some embodiments of the present disclosure, and therefore should not be considered as limiting the scope of the present disclosure. Those of ordinary skill in the art can also obtain other relevant accompanying drawings according to these accompanying drawings without creative efforts.

FIG. 1 is a schematic diagram of a exploded structure of a battery pack provided in an embodiment of the present disclosure;

FIG. 2 is a schematic structural diagram of a battery sampling assembly provided in an embodiment of the present disclosure;

FIG. 3 is a schematic diagram of a first structure of a metal sampling sheet provided in an embodiment of the present disclosure;

FIG. 4 is a schematic diagram of a first structure of a buffer section of a metal sampling sheet provided in an embodiment of the present disclosure;

FIG. 5 is a schematic exploded diagram of a first structure of a battery sampling assembly provided in an embodiment of the present disclosure;

FIG. 6 is a schematic exploded diagram of a second structure of a battery sampling assembly provided in an embodiment of the present disclosure;

FIG. 7 is a schematic diagram of a second structure of a metal sampling sheet provided in an embodiment of the present disclosure;

FIG. 8 is a schematic diagram of a second structure of a buffer section of a metal sampling sheet provided in an embodiment of the present disclosure;

FIG. 9 is a schematic diagram of a third structure of a buffer section of a metal sampling sheet provided in an embodiment of the present disclosure;

FIG. 10 is a schematic structural diagram of a first perspective of a battery pack provided in an embodiment of the present disclosure;

FIG. 11 is a schematic diagram of a partially enlarged structure of a part A in FIG. 10;

FIG. 12 is a schematic structural diagram of a second perspective of a battery pack provided in an embodiment of the present disclosure;

FIG. 13 is a schematic diagram of a partially enlarged structure of a part B in FIG. 12; and

FIG. 14 is a schematic structural diagram of a circuit board provided in an embodiment of the present disclosure.

In figures: 100—battery sampling assembly; 110—metal sampling sheet; 111—body; 113—first end portion; 115—second end portion; 117—straight section; 121—first surface; 123—second surface; 125—side surface; 130—buffer section; 131—first subsection; 133—second subsection; 135—circular arc section; 137—first arc portion; 139—second arc portion; 150—insulating film; 151—through hole; 200—battery pack; 201—first side; 203—second side; 210—battery cell; 220—busbar; 230—circuit board; 231—pin; 240—isolation support plate.

### DETAILED DESCRIPTION OF THE EMBODIMENTS

To make the objectives, technical solutions and advantages of the embodiments of the present disclosure clearer, the technical solutions in the embodiments of the present disclosure are clearly and completely described below with reference to the accompanying drawings in the embodiments of the present disclosure. Apparently, the described embodiments are merely some rather than all of the embodiments of the present disclosure. The assemblies in the embodiments of the present disclosure, generally described and shown in the accompanying drawings herein, may be arranged and designed in a variety of different configurations.

Accordingly, the following detailed descriptions of the embodiments of the present disclosure, provided in the accompanying drawings, are not intended to limit the scope of the claimed present disclosure, but merely represent selected embodiments of the present disclosure. All other embodiments obtained by those of ordinary skill in the art based on the embodiments in the present disclosure without creative efforts shall fall within the protection scope of the present disclosure.

It should be noted that similar numerals and letters denote similar items in the following accompanying drawings, therefore, once an item is defined in one accompanying drawing, it does not need to be further defined and explained in subsequent accompanying drawings.

In the description of the present disclosure, it should be noted that the orientation or position relationships indicated by terms “upper”, “lower”, “inside”, “outside” and the like are based on orientation or position relationships shown in accompanying drawings, or orientation or position relationships of products of the present invention that are commonly placed during use. The orientation or position relationships are only for the convenience of describing the present disclosure and simplifying the description, rather than indicating or implying that the mentioned apparatus or component needs to have a particular orientation or needs to be constructed and operated in a particular orientation. Therefore, this should not be understood as a limitation on the present disclosure.

In addition, the terms “first”, “second”, and the like are used to distinguish descriptions only, and cannot be construed as indicating or implying relative importance.

It should be noted that in the case of no conflict, the features in the embodiments of the present disclosure can be combined with each other.

The existing battery cells are all provided with pole columns on different sides of the battery cells, and the pole columns on two sides need to be transferred to the same side to facilitate the collection of information of battery packs. Through long-term research by inventors, it has been found that in the existing transfer modes, a wire harness transfer mode and a flexible circuit board transfer mode are mostly used.

If the wire harness transfer mode is used, the structure is complex, there are numerous wire harnesses, the connection efficiency is low, and the phenomena of short circuits, missed connection and the like easily occur in wire harnesses. If the flexible circuit board transfer mode is used, two transfer processes are required, the structure is complex, the connection efficiency is low, and the cost is high.

Therefore, to overcome at least one defect of the prior art, the present disclosure proposes a battery sampling assembly 100 which is simple in structure, convenient to install, high in connection efficiency, and beneficial for reducing the cost.

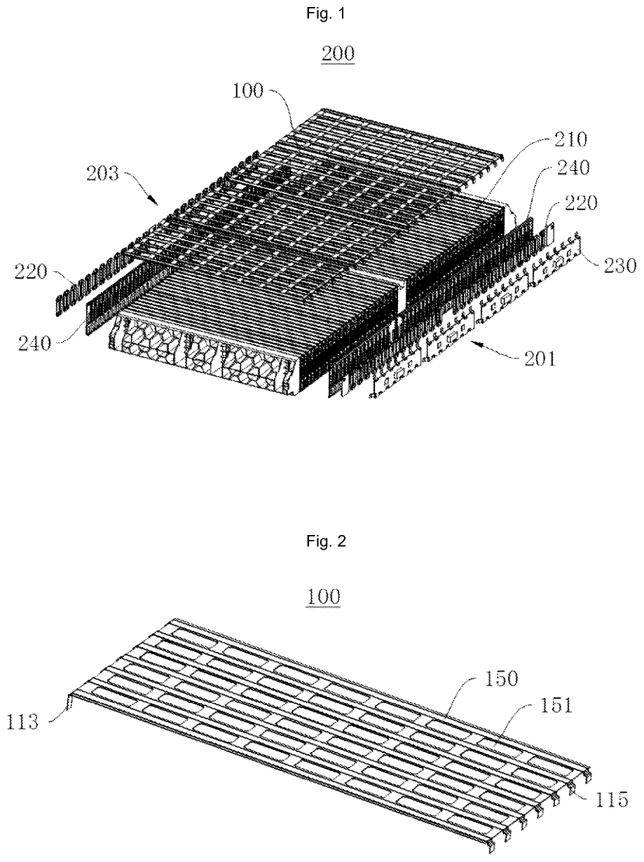

Referring to FIG. 1 to FIG. 3, the present embodiment provides a battery sampling assembly 100 which is applied to a battery pack 200 and is able to be configured to collect information of each battery cell 210 in the battery pack 200. The collected information includes but is not limited to information such as current, voltage and temperature. The battery sampling assembly 100 includes at least one metal sampling sheet 110 and at least one insulating films 150. Each of the at least one metal sampling sheet 110 includes a body 111, and a first end portion 113 and a second end portion 115 which are arranged at two ends of the body 111. The first end portion 113 is configured to be electrically connected with a busbar 220, and the second end portion 115 is configured to be electrically connected with a circuit board 230. The at least one insulating film 150 covers the body 111 of the at least one metal sampling sheet 110 and is configured to maintain the insulation contact between the metal sampling sheet 110 and the battery cell 210. The battery sampling assembly 100 is simple in structure, each of the at least one metal sampling sheet 110 is easy to install and locate, the connection is convenient, the assembly efficiency is high, and the cost is low.

In some embodiments, the metal sampling sheet 110 includes but is not limited to one or more of a gold sheet, a silver sheet, a copper sheet, an aluminum sheet, a tin sheet, a nickel sheet, an iron sheet, a cobalt sheet, and the like.

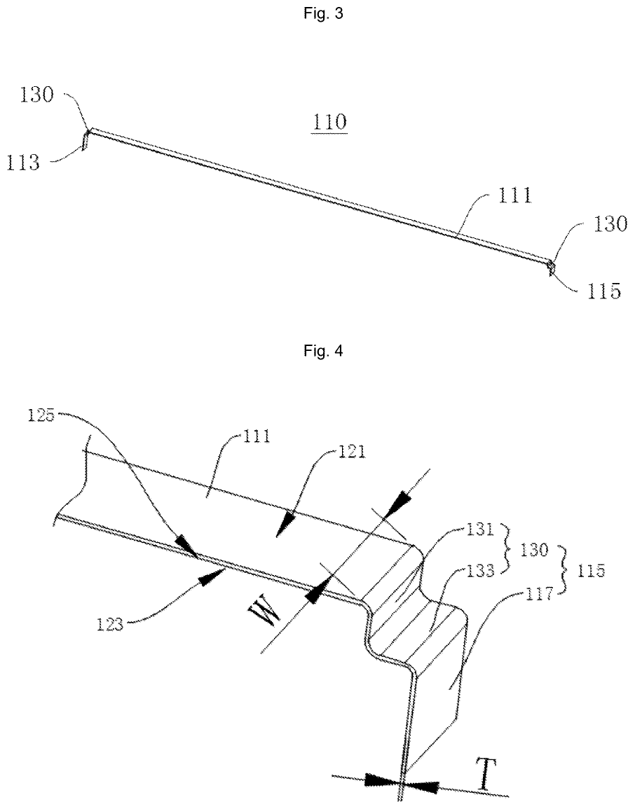

With reference to FIG. 3, in the present embodiment, the metal sampling sheet 110 is in a shape of long thin sheet, and the shape of long thin sheet is able to reduce a weight and reduce a volume and is beneficial for reducing an overall size and an occupied space of the battery pack 200. The metal sampling sheet 110 is crossed from one side of the battery cell 210 provided with pole columns to the other side of the battery cell 210 provided with pole columns, so as to transfer the pole column on one side to the other side of the battery cell 210. It should be understood that the battery cell 210 includes an upper surface, a lower surface and four circumferential side vertical surfaces, wherein the upper surface and the lower surface are arranged oppositely. The metal sampling sheet 110 is able to be arranged above the battery cell 210, that is, distributed along the upper surface of the battery cell 210. The metal sampling sheet 110 is also able to be arranged below the battery cell 210, that is, distributed along the lower surface of the battery cell 210. Or, the metal sampling sheet 110 is distributed along a side surface 125 of the battery cell 210, or the metal sampling sheet 110 is arranged in a middle of the battery cell 210 and passes through a gap between adjacent battery cells 210, so as to realize a connection between the pole column on one side of the battery cell 210 and the circuit board 230 on the other side. The distribution path of the metal sampling sheet 110 may be a straight line, a curve, a broken line, or the like, and there is no specific limitation here.

In some embodiments, a shape of a cross section of the metal sampling sheet 110 may be square, rhombic, rectangular, triangular, trapezoidal, elliptical or circular, or may be in a combined shape of multiple shapes. Or, the metal sampling sheet 110 may be in any other regular or irregular shape, and there is no specific limitation here.

With reference to FIG. 4, a ratio of the width W to a thickness T of the metal sampling sheet 110 is 10-100. In some embodiments, the thickness of the metal sampling sheet 110 is greater than or equal to 0.05 mm, which is beneficial for improving the connection strength between the metal sampling sheet 110 and the circuit board 230, or beneficial for improving the connection strength between the metal sampling sheet 110 and the busbar 220.

The body 111 of the metal sampling sheet 110 includes the side surface 125, and a first surface 121 and a second surface 123 which are arranged oppositely, and the side surface 125 is configured to connect the first surface 121 and the second surface 123. The insulating film 150 covers the first surface 121 and the second surface 123 respectively. It is easy to understand that two sides of the first surface 121 and second surface 123 of the metal sampling sheet 110 are covered with insulating films 150 respectively, so as to improve the insulation between the metal sampling sheet 110 and other electrical components to prevent short circuits. In the present embodiment, the first surface 121 is provided with a layer of the insulating film 150, the second surface 123 is provided with a layer of the insulating film 150, and one of the two layers of insulating films 150 on two sides of the first surface 121 and one of the two layers of insulating films 150 on two sides of the second surface 123 are in compression joint on the side surface 125 of the metal sampling sheet 110. In this way, the side surface 125 of the metal sampling sheet 110 is also covered with the insulating film 150 to ensure the insulation contact between the metal sampling sheet 110 and other electrical components to prevent short circuits.

Of course, the mode of covering the surface of the metal sampling sheet 110 with the insulating film 150 may be a mode of using two layers of insulating films 150 for laminating, that is, the metal sampling sheet 110 is located between the two layers of insulating films 150. One insulating film 150 may also be wound along the surface of the metal sampling sheet 110, that is, a mode of wrapping the metal sampling sheet 110 with the insulating film 150 is used, and there is no specific limitation here. Each metal sampling sheet 110 is covered with one or two insulating films 150, or a plurality of metal sampling sheets 110 are together covered with one or two insulating films 150, and there is no specific limitation here.

In some embodiments, the metal sampling sheet 110 and the insulating film 150 may be fixed in a mode of colloid bonding, which is beneficial for improving the adhesion and connection stability between the insulating film 150 and the metal sampling sheet 110. Colloids may use thermal conductive adhesives to improve heat dissipation. A thickness of the insulating film 150 is 0.03-0.5 mm, such as 0.05 mm, 0.1 mm, 0.2 mm, 0.3 mm, 0.4 mm, 0.5 mm, or any value within the range. The thickness of the insulating film 150 should be understood as the thickness of the insulating film 150 covered on one side of the metal sampling sheet 110. If the first surface 121 is covered with a layer of insulating film 150, the thickness of the layer of insulating film 150 is 0.03-0.5 mm. If the first surface 121 is covered with multiple layers of insulating films 150, the sum of the thicknesses of the multiple layers of insulating films 150 is 0.03-0.5 mm. The insulating film 150 may be made of one or more of polypropylene (PP), polyethylene terephthalate (PET), polycarbonate, polyimide, and the like.

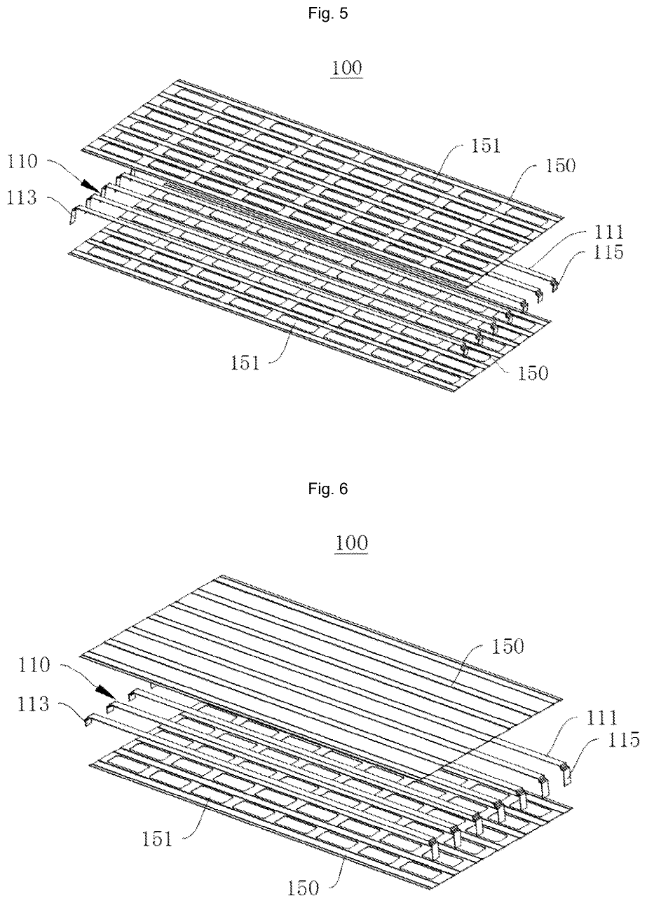

With reference to FIG. 5 and FIG. 6, it should be noted that one battery sampling assembly 100 includes a plurality of metal sampling sheets 110 arranged at intervals side by side, that is, a plurality of metal sampling sheets 110 are provided. In some embodiments, a distance between two adjacent metal sampling sheets 110 is greater than or equal to 2 mm. In some embodiments, a length of each metal sampling sheet 110 is consistent, resulting in higher sampling accuracy.

Each metal sampling sheet 110 may be covered with an independent insulating film 150, or one insulating film 150 may simultaneously cover a plurality of metal sampling sheets 110. In a case that a layer of insulating film 150 simultaneously covers a plurality of metal sampling sheets 110, the insulating film 150 may be provided with at least one through hole 151, and the at least one through hole 151 and the metal sampling sheet 110 are arranged at an interval, that is, each of the at least one through hole 151 is arranged between two adjacent metal sampling sheets 110. The through hole 151 is able to achieve weight reduction and heat dissipation effects.

In some embodiments, the insulating films 150 on two sides of the metal sampling sheet 110 may be provided with through holes 151 respectively, or the insulating film 150 on one side is provided with through holes 151. If the insulating films 150 on two sides are provided with through holes 151, the through holes 151 on the two sides may be arranged correspondingly or arranged in a staggered mode. The staggered arrangement may be understood as complete staggered arrangement or partial staggered arrangement. The complete staggered arrangement means that the projection region of the through holes 151 on one side on the metal sampling sheet 110 does not overlap with the projection region of the through holes 151 on the other side on the metal sampling sheet 110. The partial staggered arrangement means that the projection region of the through holes 151 on one side on the metal sampling sheet 110 partially overlaps with the projection region of the through holes 151 on the other side on the metal sampling sheet 110. The corresponding arrangement is able to be understood that the projection region of the through holes 151 on one side on the metal sampling sheet 110 completely overlaps with the projection region of the through holes 151 on the other side on the metal sampling sheet 110. The number and shape of the through holes 151 and the arrangement of the through holes 151 on the insulating film 150 are able to be flexibly adjusted according to actual situations, and there is no specific limitation here. If the through holes 151 on the insulating films 150 on two sides are correspondingly arranged partially or completely, colloids or other media may also be directly injected into the battery cell 210 from the through holes 151, thereby facilitating the simplification of the production process of the battery pack 200 and improving the production efficiency of the battery pack 200.

Of course, in some embodiments, the through holes 151 on the insulating film 150 may also be omitted, such as the structure of the insulating film 150 on one side of the first surface 121 of the body 111 shown in FIG. 6. In an embodiment corresponding to FIG. 6, the insulating film 150 on one side of the first surface 121 of the body 111 is not provided with through holes 151, and the insulating film 150 on one side of the second surface 123 of the body 111 is provided with through holes 151.

It should be noted that the insulating film 150 only covers the body 111 of the metal sampling sheet 110, and the first end portion 113 and second end portion 115 of the metal sampling sheet 110 serve as electrical connection ends and are not provided with insulating film 150. The first end portion 113 and the second end portion 115 are metal exposed portions, and a length of the first end portion 113 and a length of the second end portion 115 are greater than or equal to 5 mm respectively to ensure reliable electrical connection between the metal sampling sheet 110 and the circuit board 230 or the busbar 220.

In some embodiments, still referring to FIG. 4, the first end portion 113 and the second end portion 115 are respectively provided with straight sections 117, and a length of the straight section 117 is greater than or equal to 3 mm. The straight section 117 is configured as an effective electrical connection region between the metal sampling sheet 110 and the circuit board 230 or the busbar 220. For example, the straight section 117 is welded to the circuit board 230 or the busbar 220 respectively. The length of the straight section 117 is set to be greater than or equal to 3 mm, which is beneficial for ensuring the reliability and stability of welding, improving the welding strength, and improving the stability of electrical connection. The structure of the first end portion 113 is similar to the structure of the second end portion 115, FIG. 4 only shows the structure of the second end portion 115, and the structure of the first end portion 113 is not described here.

In some embodiments, the metal sampling sheet 110 is provided with a buffer section 130, and the length of the metal sampling sheet 110 is able to be adjusted by the buffer section 130. The arrangement of the buffer section 130 is beneficial for solving a problem of installation failure caused by position errors in an installation process, is able to reduce the requirement for installation accuracy, is able to achieve smooth assembly within an allowed location error range, and has better compatibility. In addition, the buffer section 130 is also able to prevent the failure of the connection of the metal sampling sheet 110 caused by violent shaking or swaying during the use of the battery pack 200, and has certain shock absorption and buffering effects.

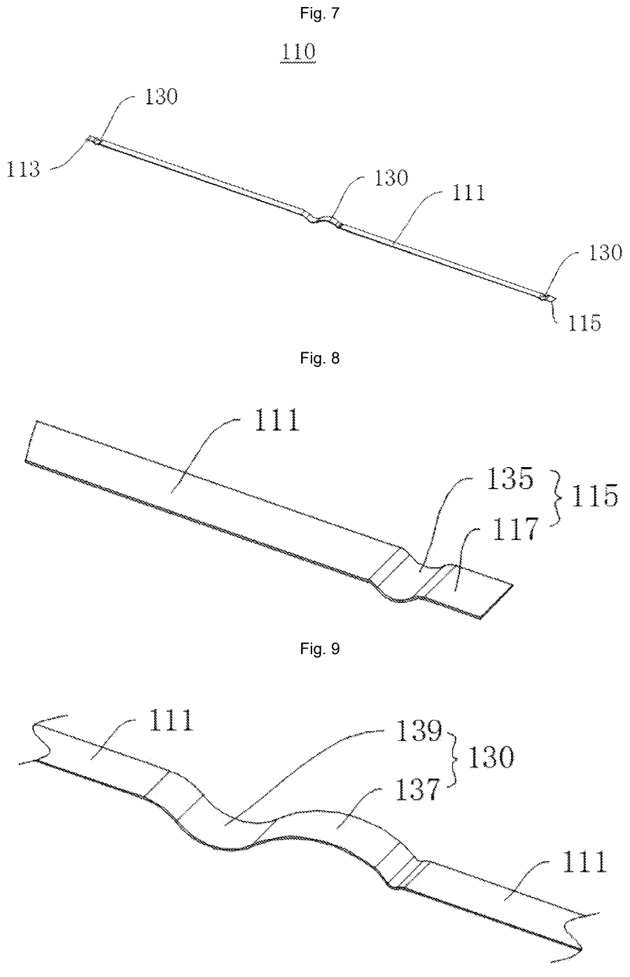

The buffer section 130 may be arranged at any position of the metal sampling sheet 110, for example, arranged in at least one of the first end portion 113, the second end portion 115 and the body 111. As shown in FIG. 3, the buffer sections 130 are arranged at the first end portion 113 and the second end portion 115 respectively. As shown in FIG. 7, the buffer sections 130 are arranged at the first end portion 113, the second end portion 115 and the body 111 respectively. The cross section of the buffer section 130 may be a bent surface or any curved surface, may be in any shape such as a circular arc shape, a wave shape, a W shape, a U shape, a V shape or a Z shape, or may also be in a pulse shape, a spiral shape, or the like. One or a plurality of buffer sections 130 may be provided, and there is no specific limitation here.

In some embodiments, with reference to FIG. 4, taking the buffer section 130 arranged at the second end portion 115 as an example, the second end portion 115 includes a buffer section 130 and a straight section 117 which are connected with each other, and the buffer section 130 is connected with the body 111. In some embodiments, the buffer section 130 is an L-shaped bent section, that is, the buffer section 130 includes a first subsection 131 and a second subsection 133 which are connected with each other, the first subsection 131 is connected with the body 111, and the second subsection 133 is connected with the straight section 117. The first subsection 131 and the second subsection 133 are arranged at an angle. In the present embodiment, the upper and lower directions are defined as: the first surface 121 faces upwards, and the second surface 123 faces downwards. The first subsection 131 extends downwards from the body 111, and the second subsection 133 extends towards the direction away from the body 111 from the first subsection 131. The straight section 117 extends towards the direction away from the body 111 from the second subsection 133, that is, the straight section 117 extends downwards and is parallel to the first subsection 131. A joint between the first subsection 131 and the body 111, a joint between the second subsection 133 and the first subsection 131, and a joint between the straight section 117 and the second subsection 133 are all in circular arc transition connection, so that the stress concentration of the structure is reduced, and the buffering effect is better.

It should be noted that the arrangement direction of the straight section 117 is not limited to the extension direction shown in the figure, and is able to be flexibly set according to actual needs, as long as it is convenient to weld the straight section 117 of the first end portion 113 to the busbar 220, and convenient to weld the straight section 117 of the second end portion 115 to pins 231 of the circuit board 230.

With reference to FIG. 8, in some embodiments, the buffer section 130 is a circular arc section 135, one end of the circular arc section 135 is connected with the body 111, and the other end of the circular arc section 135 is connected with the straight section 117. The circular arc section 135 may be convexly arranged upwards or concavely arranged downwards or may be arranged in a wave shape, and there is no specific limitation here.

With reference to FIG. 9, in some embodiments, taking the buffer section 130 arranged at the body 111 as an example, the buffer section 130 includes a first arc portion 137 and a second arc portion 139 which are connected with each other, and a concave direction of the first arc portion 137 is opposite to a concave direction of the second arc portion 139, wherein the first arc portion 137 is connected with the body 111 close to the second end portion 115, the second arc portion 139 is connected with the body 111 close to the first end portion 113, the first arc portion 137 is convexly arranged upwards, and the second arc portion 139 is concavely arranged downwards. The first arc portion 137 and the second arc portion 139 are in smooth transition connection along a cross section. The first arc portion 137 and the second arc portion 139 are in circular arc transition connection with the body 111 respectively to reduce the stress concentration of the structure.

In some embodiments, the first end portion 113, the second end portion 115 and the body 111 are respectively provided with buffer sections 130, and the shapes and sizes of the buffer sections 130 may be the same or different. The number of the buffer sections 130 in each subsection on the metal sampling sheet 110 may be the same or different. For example, the first end portion 113 and the second end portion 115 are respectively provided with a buffer section 130, the body 111 is provided with a plurality of buffer sections 130, and there is no specific limitation here. In some embodiments, the entire metal sampling sheet 110 may be integrally formed or connected in sections, that is, the first end portion 113, the body 111, the second end portion 115 and the buffer section 130 may be integrally formed or connected in sections.

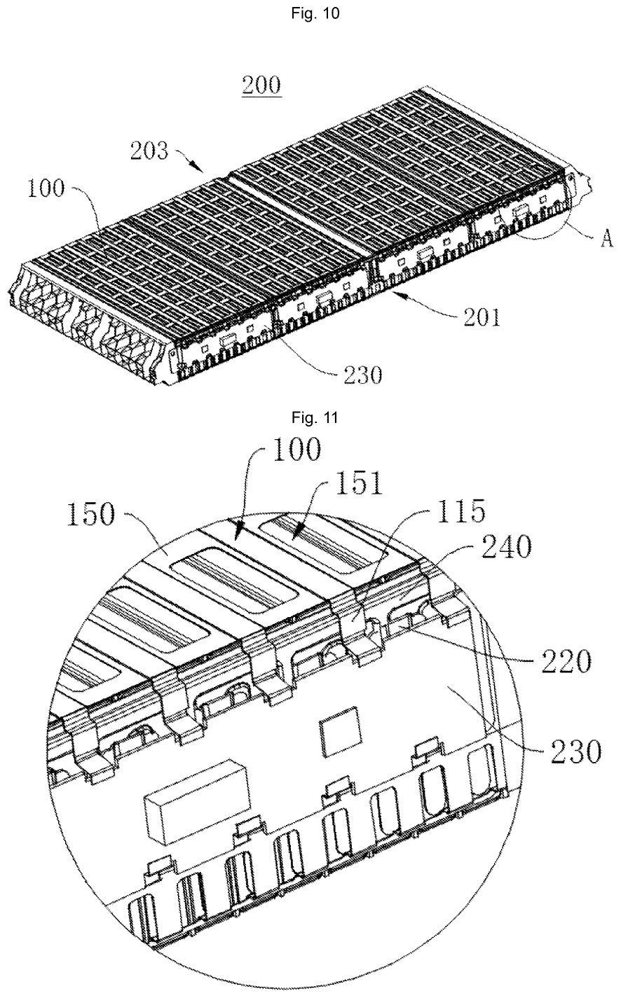

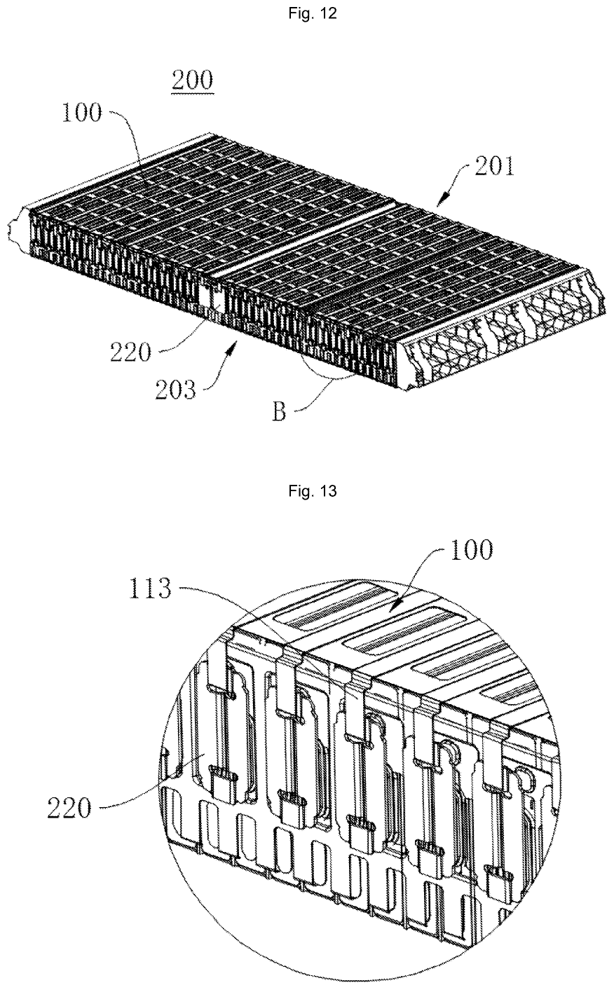

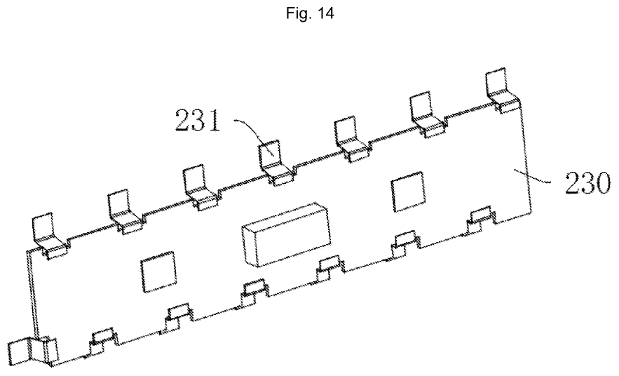

With reference to FIG. 1 and FIG. 10 to FIG. 14, an embodiment of the present disclosure further provides a battery pack 200, including a plurality of battery cells 210, busbars 220, a circuit board 230 and the above battery sampling assemblies 100. The busbars 220 are separately arranged on two sides of the battery cells 210 provided with pole columns, and the busbars 220 are electrically connected with the pole columns of the plurality of battery cells 210 respectively. The circuit board 230 is arranged on one of the two sides of the battery cells 210 provided with pole columns. The busbar 220 located on the same side of the battery cell 210 as the circuit board 230 is electrically connected with the circuit board 230. The battery sampling assembly 100 is straddled on two sides of the battery cell 210 provided with pole columns, wherein the first end portion 113 of the metal sampling sheet 110 is electrically connected with the busbar 220 on a side away from the circuit board 230, and the second end portion 115 of the metal sampling sheet 110 is electrically connected with the circuit board 230. The busbar 220 on the side away from the circuit board 230 is transferred to the other side opposite to the battery cell 210 through the metal sampling sheet 110, so as to facilitate the collection of the information of the battery cell 210 on the same side. The battery sampling assembly 100 of the battery pack 200 is simple in structure, convenient to connect, high in connection efficiency, stable and reliable in electrical connection, beneficial for improving the sampling efficiency and the sampling stability, and relatively low in production cost.

It is able to be understood that the battery cell 210 includes a first side 201 and a second side 203 which are arranged oppositely, the first side 201 and the second side 203 are respectively provided with pole columns, the first side 201 and the second side 203 are respectively provided with busbars 220, the busbar 220 of the first side 201 is electrically connected with the pole column of the first side 201, and the busbar 220 of the second side 203 is electrically connected with the pole column of the second side 203. In some embodiments, the first side 201 and the second side 203 are respectively provided with isolation support plates 240, the isolation support plate 240 is arranged between the battery cell 210 and the busbar 220, the isolation support plate 240 is able to achieve support and insulation isolation effects, and the isolation support plate 240 is able to also achieve a locating effect in an assembly process to improve the assembly efficiency.

The circuit board 230 is arranged on the first side 201 or the second side 203 of the battery cell 210. In the present embodiment, the circuit board 230 is arranged on the first side 201, the circuit board 230 is fixedly connected with the isolation support plate 240 on the first side 201, and the circuit board 230 is electrically connected with the busbar 220 on the first side 201. In some embodiments, the circuit board 230 is provided with a plurality of pins 231, and each pin 231 is welded to the second end portion 115 to achieve the electrical connection between the circuit board 230 and the metal sampling sheet 110.

The first end portion 113 of the metal sampling sheet 110 is welded to the busbar 220 on the second side 203. The welding includes but is not limited to any one of laser welding, resistance welding, or ultrasonic bonding. Or, the first end portion 113 and the busbar 220 on the second side 203 are riveted, connected by screws, or bonded by a conductive adhesive. Similarly, the mode of electrical connection between the pin 231 and the second end portion 115 includes but is not limited to laser welding, resistance welding, ultrasonic welding, riveting, screw connection, conductive adhesive bonding, or the like.

In some embodiments, in each battery pack 200, one or a plurality of battery sampling assemblies 100 may be provided, a plurality of battery sampling assemblies 100 are arranged side by side, and the number of battery sampling assemblies 100 is flexibly adjusted according to the actual number of battery cells 210 and the size of the battery pack 200, so as to ensure that all pole columns on the second side 203 are transferred to the circuit board 230.

The working principle of the battery sampling assembly 100 and the battery pack 200 provided in the embodiments of the present disclosure is as follows:

The battery sampling assembly 100 is straddled on the first side 201 and the second side 203 of the battery cell 210 provided with pole columns, the first end portion 113 is electrically connected with the busbar 220 on the second side 203, and the second end portion 115 is electrically connected with the circuit board 230 on the first side 201. The busbar 220 on the second side 203 is transferred to the circuit board 230 on the first side 201 through the metal sampling sheet 110, the circuit board 230 on the first side 201 is electrically connected with the busbar 220 on the first side 201, and thus, the circuit board 230 is able to simultaneously collect the information of the two sides of the battery cell 210.

Based on the above, the battery sampling assembly 100 and the battery pack 200 provided in the embodiments of the present disclosure have the beneficial effects, for example:

The battery sampling assembly 100 provided in the embodiments of the present disclosure includes the metal sampling sheets 110 and the insulating films 150 arranged on the metal sampling sheets 110, and two ends of each of the metal sampling sheets 110 are electrically connected with the busbar 220 and the circuit board 230 respectively, so that the sampling of the battery cell 210 is able to be achieved, the structure is simple, the electrical connection is stable and reliable, the metal sampling sheet 110 is easy to install and locate, the connection is convenient, and the cost is low. Furthermore, the metal sampling sheet 110 uses a metal sheet which is small in volume and light in weight. The length of each metal sampling sheet 110 is consistent, resulting in higher sampling accuracy. By arranging the buffer section 130, the length adjustment of the metal sampling sheet 110 is able to be achieved, installation and connection are facilitated, the installation accuracy is reduced, and the problem of tensile breakage or connection failure during use or movement is able to also be prevented.

The battery pack 200 provided in the embodiments of the present disclosure includes the above battery sampling assembly 100, the sampling structure is simple, the battery pack 200 is convenient to assemble, and the increase in sampling efficiency and stability is facilitated.

The above descriptions are only specific implementations of the present disclosure, but the protection scope of the present disclosure is not limited to this. Any variation or replacement readily figured out by a person skilled in the art within the technical scope disclosed in the present disclosure shall fall within the protection scope of the present disclosure. Therefore, the protection scope of the present disclosure shall be determined with reference to the protection scope of the claims.

### Industrial Applicability

The embodiments of the present disclosure provide a battery sampling assembly 100 and a battery pack 200, which is able to simplify a sampling structure and reduce the cost and are beneficial for improving the sampling efficiency and stability.

1-20. (canceled)

21. A battery sampling assembly, configured to collect information of a plurality of battery cells of a battery pack, comprising: a sampling sheet and an insulating film; wherein
each of the metal sampling sheet is in a shape of long thin sheet, and comprises a body, and a first end portion and a second end portion which are arranged at two ends of the body; and
the insulating film covers the body of the metal sampling sheet;
a ratio of a width to a thickness of the each of the metal sampling sheet is 10-100;
a thickness of the each of the metal sampling sheet is greater than or equal to 0.05 mm.
the battery sampling is straddled on a first side and a second side disposed opposite to each other of the plurality of battery cells of the battery pack, wherein a pole of the first side is electrically connected with a first busbar of the first side, a pole of the second side is electrically connected with the second busbar of the second side, and the second busbar is electrically connected with a circuit board of the second side;
the first end portion is configured to be electrically connected with the first busbar, and the second end portion is configured to be electrically connected with a circuit board.

22. The battery sampling assembly as claimed in claim 21, wherein the first end portion and the second end portion are respectively provided with straight sections, the straight sections are configured as an electrical connection region between the metal sampling sheet and the circuit board or the busbar, and a length of each of the straight sections is greater than or equal to 3 mm.

23. The battery sampling assembly as claimed in claim 22, wherein the each of the metal sampling sheet is provided with a buffer section, and a length of the each of the metal sampling sheet is configured to be adjusted by the buffer section.

24. The battery sampling assembly as claimed in claim 23, wherein the buffer section is arranged on the first end portion and/or the second end portion, the buffer section comprises a first subsection and a second subsection which are connected with each other, and the first end portion and the second end portion are respectively provided with straight sections; and the first subsection is connected with the body, and the second subsection is connected with a corresponding straight section of the straight sections.

25. The battery sampling assembly as claimed in claim 23, wherein the buffer section is arranged on the body, the buffer section comprises a first arc portion and a second arc portion which are connected with each other, and a concave direction of the first arc portion is opposite to a concave direction of the second arc portion; the first arc portion is in circular arc transition connection with the body close to the second end portion, and the second arc portion is in circular arc transition connection with the body close to the first end portion.

26. The battery sampling assembly as claimed in claim 21, wherein the body of the each of the metal sampling sheet comprises a side surface, and a first surface and a second surface which are arranged oppositely, the side surface is connected with the first surface and the second surface respectively, and the insulating film comprises a first insulating film and a second insulating film, the first surface is provided with the first insulating film, the second surface is provided with the second insulating film, and the first insulating film and the second insulating film are in compression joint on the side surface.

27. The battery sampling assembly as claimed in claim 21, wherein a plurality of metal sampling sheets are provided, and a distance between two adjacent metal sampling sheets in the plurality of metal sampling sheets is greater than or equal to 2 mm.

28. The battery sampling assembly as claimed in claim 27, wherein a plurality of metal sampling sheets are together covered with the insulating film, the insulating film is provided with through holes, each of the through holes is located between two adjacent metal sampling sheets in the plurality of metal sampling sheets.

29. The battery sampling assembly as claimed in claim 21, wherein a shape of a cross section of the metal sampling sheet may be square, rhombic, rectangular, triangular, trapezoidal, elliptical or circular, or may be in a combined shape of multiple shapes.

30. The battery sampling assembly as claimed in claim 29, wherein the metal sampling sheet is able to be arranged above, below or at a side surface of the plurality of battery cells.

31. The battery sampling assembly as claimed in claim 21, wherein a thickness of each of the insulating film is 0.03 mm-0.5 mm.

32. The battery sampling assembly as claimed in claim 21, wherein the insulating film may be made of one or more of polypropylene, polyethylene terephthalate, polycarbonate, and polyimide.

33. The battery sampling assembly as claimed in claim 21, wherein the metal sampling sheet and the insulating film are fixed by colloid bonding.

34. A battery pack, comprising:
a plurality of cells;
busbars;
a circuit board; and
the battery sampling assembly as claimed in claim 21.

35. The battery pack as claimed in claim 34, wherein the battery sampling assembly further comprises an isolation support plate, the isolation support plate is arranged between the plurality of battery cells and the busbar.
